(19) United States
(12) Patent Application Publication
(10) Pub. No.: US 2026/0195632 A1
(43) Pub. Date: Jul. 9, 2026

(54) Method for Evaluating a Sensor Model, Method for Training a Recognition Algorithm, and Sensor System

(71) Applicant: Robert Bosch GmbH, Stuttgart (DE)

(72) Inventor: Thanh Danh Anthony Ngo, Usingen (DE)

(21) Appl. No.: 18/877,471

(22) PCT Filed: Jun. 21, 2023
(86) PCT No.: PCT/EP2023/066724

§ 371 Date: Sep. 19, 2025

(30) Foreign Application Priority Data
Jun. 23, 2022 (DE) 10 2022 206 347.3

(51) Int. Cl. G06N 20/00; G06F 30/20

(52) U.S. Cl. CPC G06N 20/00; G06F 30/20

(57) ABSTRACT

A method is for evaluating a sensor model in which real-world sensor data is compared to simulated sensor data. The following steps are carried out for this purpose. First, the sensor parameters to be analyzed and a range of values for each of the sensor parameters to be analyzed are defined. Subsequently, input values for the sensor model are generated. First input values are generated by a simulation of a behavior of a sensor and second input values comprise real sensor values. Thereafter, simulation of the behavior of the sensor is evaluated for accuracy and for computing time. Finally, a sensitivity analysis is performed based on the accuracy and the computing time.

### The invention relates to a method for evaluating a sensor model, a method for training a detection algorithm, and a sensor system.

### PRIOR ART

Sensor systems are known, for example for use in vehicles, in particular motor vehicles. One focus of the current development is the automated execution of driving functions, starting with driver assistance systems that support a driver of the vehicle, up to vehicles that can drive in certain areas or even drive fully autonomously. Carrying out driving functions automatically requires providing sensor systems in the vehicles to detect and classify a surrounding environment of the vehicle to use this information in trajectory planning and/or control driving functions based on this information. The sensor systems, including evaluation electronics, must be extensively tested and validated before use in vehicles in order to be as sure as possible that all relevant information is identified by the sensor systems and that no relevant information is missed. This can be done in particular using simulated sensor data, wherein the advantage of such data is that relevant situations can be explicitly inserted into the simulated sensor data and so the sensor systems can be evaluated with regard to all relevant situations. If only real-world sensor data were used, even in an ideal case, this would only be achieved by extremely extensive test runs, wherein even this cannot guarantee that all eventualities are truly covered.

Relevant sensor models are then created for the sensor systems. These sensor models may be used to evaluate the behavior of the sensor system in a simulated environment. Further elements of a controller, such as object detection, can then be evaluated with the simulated environment and the downstream behavior of the sensor system, wherein a number of test runs can be reduced. However, these simulations are very complex and require extensive computing power.

### DISCLOSURE OF THE INVENTION

One object of the invention is to provide a method for evaluating a sensor model with a reduced need for computing power. A further object of the invention is to provide a method for training a detection algorithm based on the method according to the invention for evaluating the sensor model. A further object of the invention is to provide a sensor system trained with the method according to the invention for training a detection algorithm. Said objects are achieved by the subject matters of the independent patent claims. Advantageous further embodiments are given in the dependent claims.

In a method for evaluating a sensor model, real-world sensor data is compared to simulated sensor data. The following steps are carried out for this purpose. First, the sensor parameters to be analyzed and a range of values for each of the sensor parameters to be analyzed are defined. Subsequently, input values for the sensor model are generated, wherein first input values are generated by a simulation of a behavior of a sensor and second input values comprise real sensor values. Thereafter, simulation of the behavior of the sensor is evaluated for accuracy and for computing time. Finally, a sensitivity analysis is performed based on the accuracy and the computing time.

By means of the sensitivity analysis, those sensor parameters that require a disproportionately large amount of computing time compared to a gain in accuracy for these sensor parameters can be adjusted, or their ranges of values can be adjusted. This allows better utilization of an existing computational capacity, thereby providing an improved sensor model, where less computational power is required relative to accuracy. This makes it possible to provide more efficient sensor models.

The second input values may be the real, direct sensor values. Further, the second input values may also be values derived from the real sensor values. Both are intended to be included by the word “comprise”.

The sensor parameters may optionally be different for different sensor systems to be simulated. Radar sensor systems, lidar sensor systems, and camera sensor systems may in particular be relevant. For radar sensor systems, in particular, the sensor parameters may include a standard deviation of an average noise of the sensor data, a shift of detection probability, a maximum antenna amplification, a measure of a noise, an overall system loss, and/or an average radar cross-section. For lidar sensor systems, the sensor parameters may in particular comprise a number of scan layers, an array of the scan layers, an intensity, a motion blur, a rolling shutter, and/or an atmospheric attenuation. In the case of a camera sensor system, the sensor parameters may in particular comprise a vignetting, a lens distortion, an influence of a color filter, a windshield model and/or weather influences.

In one embodiment, in the sensitivity analysis, a quotient of accuracy and computing time is determined. Then, the sensor parameter is set to a defined value for which the quotient of accuracy and computing time is as small as possible. This allows the sensor model to be simplified, wherein the sensor parameter set to the defined value is as advantageous as possible for a ratio of accuracy and required computing time. For example, a first sensor parameter might have a greater impact on the simulation result than a second sensor parameter. However, if more computing time can be saved in relation to the worse accuracy by setting the first sensor parameter at a defined value, it may still be advantageous to neglect this sensor parameter in the simulation by setting the sensor parameter to the defined value.

The method is repeated in one embodiment. During the repetition, the other sensor parameters are set to a defined value for which the quotient of accuracy and computing time is as small as possible. Thus, further simplification of the sensor model may be achieved.

In one embodiment, the method is repeated until all sensor parameters are set to a defined value where the quotient of accuracy and computing time is below a predetermined value. Thus, further simplification of the sensor model may be achieved.

In one embodiment, the first input values are compared to the second input values to assess the simulation of the sensor's behavior with regard to accuracy. This may be particularly useful in determining how well the simulation of the behavior of the sensor matches real-world sensor data. For example, during the simulation, a real trip by a vehicle may be replicated with a corresponding sensor system and then the real-world sensor data may be compared to the simulated sensor data. This is an easy to implement process.

In one embodiment, the computing time is measured when assessing the simulation of the behavior of the sensor with respect to the computing time. In particular, the computing time may be measured once while a sensor parameter is set to a defined value and once when the sensor parameter is variable. A difference between these two computing times then yields the computing time according to which the simulation of the behavior of the sensor with regard to computing time is evaluated.

In one embodiment, the second input values are generated by means of a sensor.

In one embodiment, a scenario for the first input values is determined from the second input values. This may allow predetermined scenarios which were simulated by means of a real measurement run to be altered such that scenarios for which a real measurement run was not performed can now also be considered.

The method according to the invention for evaluating a sensor model can be used in a method for training a detection algorithm. In the method for training a detection algorithm, the detection algorithm is trained with simulated sensor data, wherein the simulated sensor data is evaluated using the method according to the invention for evaluating a sensor model. In this way, the simulated sensor data can be generated so as to improve utilization of the available computing time during the simulation compared to the methods known in the prior art.

The invention further comprises a sensor system, in particular a sensor system for use in a vehicle, having a sensor and a detection unit. The evaluation unit is configured to carry out a detection algorithm. The detection algorithm is trained with the method according to the invention for training the detection algorithm. The sensor system may in particular be a radar sensor system having a radar sensor, a lidar sensor system having a lidar sensor, and/or a camera sensor system having a camera.

Exemplary embodiments of the invention are explained with reference to the following drawings. Shown in the schematic drawing are:

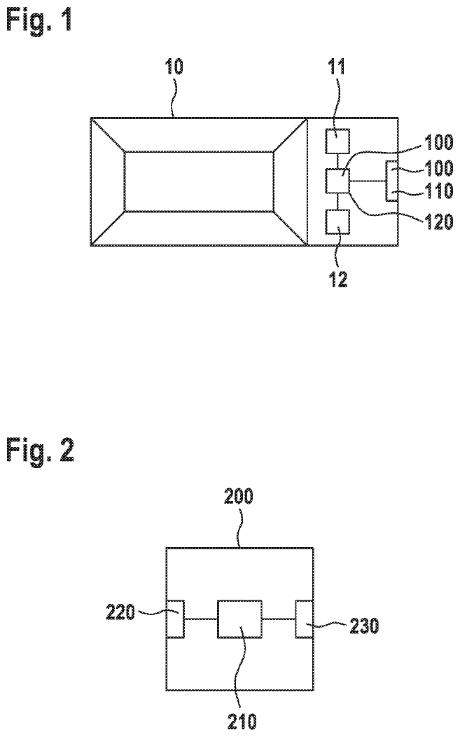

FIG. 1 a vehicle;

FIG. 2 a computing unit;

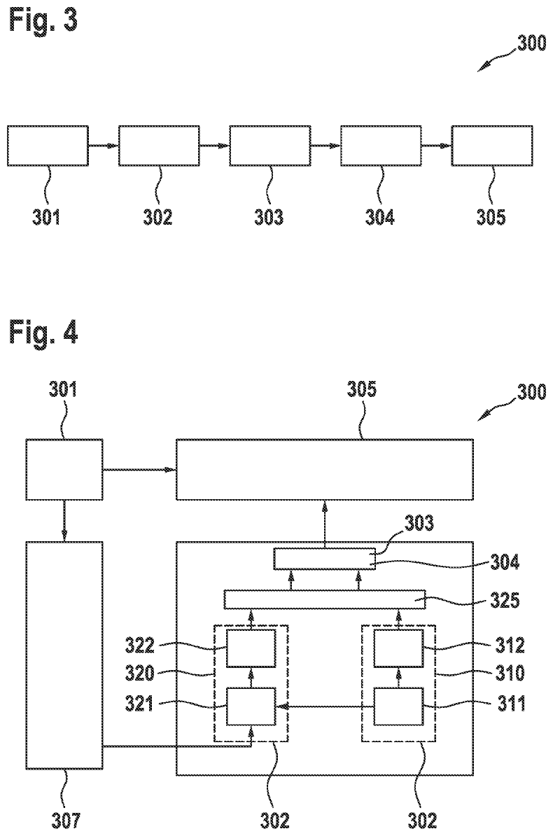

FIG. 3 a first flowchart of a method for evaluating a sensor model;

FIG. 4 a second flowchart of a method for evaluating a sensor model;

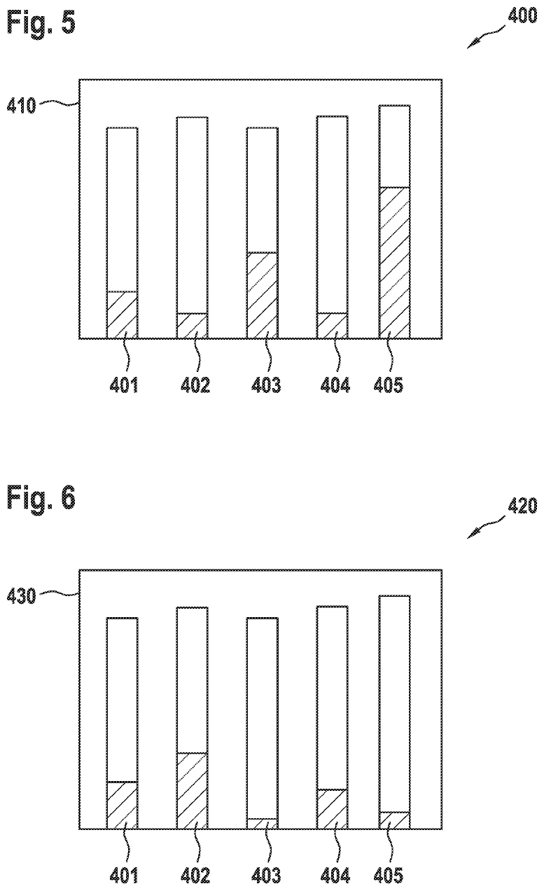

FIG. 5 a graph of an accuracy assessment; and

FIG. 6 a graph of a computing time assessment.

FIG. 1 shows a vehicle 10 with a sensor system 100. The sensor system 100 comprises at least one sensor 110 and an evaluation unit 120. The sensor system 100 may comprise a radar sensor system 100 having a radar sensor 110, a lidar sensor system 100 having a lidar sensor 110, and/or a camera sensor system 100 having a camera 110. Thus, more than one type of sensor systems 100 may also be disposed in the vehicle 10. The evaluation unit 120 is respectively configured to process signals from the sensor 110 and output them to further control units 11, 12. The further control units 11, 12 can comprise a control unit 11 for automated execution of a driving function or a control unit 12 for other functions. The control unit 11 for automated execution of a driving function may be associated with a driver assistance system that assists a driver of the vehicle 10. Alternatively, it may be provided that autonomous driving may be enabled in certain areas or fully autonomous driving may be enabled by means of the control unit 11 for the automated execution of a driving function. For the automated execution of driving functions, it is necessary to provide a sensor system 100 in the vehicle 10 with which a surrounding environment of the vehicle 10 can be detected and classified, in order to use this information in trajectory planning and/or to control driving functions based on this information. The sensor system 10, including the evaluation unit 120, must be extensively tested and validated prior to use in the vehicle 10 in order to be as sure as possible that all relevant information is identified by the sensor system 10 and that no relevant information is missed. The vehicle shown in FIG. 1 may be used in a method for evaluating a sensor model and, in particular, may provide real-world sensor data, wherein the real-world sensor data may be recorded as physical measurement data using the sensor 110 and converted to digital data using the evaluation unit 120.

FIG. 2 shows a computing unit 200 that can be used to perform a method for evaluating a sensor model. The computing unit 200 comprises a processor 210, wherein a computer program may run on the processor 210. Further, the computing unit 200 comprises an input interface 220 and an output interface 230. For example, real-world sensor data may be read by the sensor system 100 of the vehicle 10 via the input interface 220. A simulation result may be output via the output interface 230.

The computing unit 200 may further be configured to generate simulated sensor data. Relevant situations can be explicitly incorporated into the simulated sensor data, and so the sensor system 100 can be evaluated for all relevant situations. If only real-world sensor data were used, even in an ideal case, this would only be achieved by extremely extensive test runs, wherein even this cannot guarantee that all eventualities are truly covered.

FIG. 3 shows a flowchart 300 of a method for evaluating a sensor model in which real-world sensor data is compared to simulated sensor data. The real-world sensor data may have been recorded by means of the sensor system 100, in particular as explained in connection with FIG. 1. The method may in particular be performed on a computing unit 200 as shown in FIG. 2.

In a first method step 301, sensor parameters to be analyzed and a range of values for each of the sensor parameters to be analyzed are each defined. In a second method step 302, input values for the sensor model are generated, wherein first input values are generated by a simulation of a behavior of a sensor 110 and second input values comprise real sensor values, in particular real sensor values of the sensor 110. In a third method step 303, the simulation of the behavior of the sensor 110 is evaluated with regard to accuracy. In a fourth method step 304, the simulation of the behavior of the sensor 110 is evaluated with regard to computing time. In a fifth method step 305, a sensitivity analysis is performed using the accuracy and the computing time. The third method step 303 and the fourth method step 304 may also be carried out in reverse order or simultaneously.

In one exemplary embodiment, a quotient of accuracy and computing time is determined in the sensitivity analysis of the fifth method step 305. Then, the sensor parameter is set to a defined value for which the quotient of accuracy and computing time is as small as possible. The sensor model may be simplified in this way, wherein the computing unit 200 requires less computing capacity to simulate the simplified sensor model.

In one exemplary embodiment, the method is subsequently repeated with all five method steps 301, 302, 303, 304, 305. Now, the further sensor parameters for which the quotient of accuracy and computing time is as small as possible are set to a defined value. The sensor model may be further simplified in this way.

In one exemplary embodiment, the method is repeated until all sensor parameters are set to a defined value where the quotient of accuracy and computing time is below a predetermined value.

FIG. 4 shows a flowchart 300 of a method for evaluating a sensor model in which the method steps 301, 302, 303, 304, 305 discussed in connection with FIG. 3 are also performed and further options are described. The further options may also be provided individually, if necessary, and supplement the method of FIG. 3. During a parameter generation 307, sensor parameter values are respectively generated within the one range of values of the sensor parameters to be analyzed. In the second method step 302, real values are generated 310 by means of a test drive 311 of the vehicle 10, wherein sensor data 312 is generated during the test drive 311 by means of the sensors 110 or the sensor system 100. Further, in the second method step 302, synthetic generation 320 takes place, in which a simulation 321 of the behavior of the sensor 110 or the sensor system 100 is performed and sensor model data 322 is subsequently generated. The sensor model data 322 makes up the first input values and the sensor data 312 makes up the second input values. The sensor data 312 and the sensor model data 322 are then further processed in a test environment 325, which may comprise, for example, a system under test, and then the third method step 303 and the fourth method step 304 are performed. Finally, the fifth method step 305 is also performed in this method.

In one exemplary embodiment, the first input values and the second input values are compared, i.e., the sensor data 312 and the sensor model data 322 are compared, if relevant, to assess the behavior of the sensor 110 with regard to accuracy.

In one exemplary embodiment, the computing time is measured in the fourth method step 304 to assess the simulation of the behavior of the sensor 110 with respect to the computing time. This may be done, for example, by means of a clock provided within the computing unit 200.

In one exemplary embodiment, the second input values are generated by means of a sensor 110. In one exemplary embodiment, a scenario for the first input values is defined based on the second input values. This is indicated in FIG. 4 by an arrow from test drive 311 to simulation 321.

FIG. 5 shows an accuracy diagram 400, in which an accuracy 410 of a first sensor parameter 401, a second sensor parameter 402, a third sensor parameter 403, a fourth sensor parameter 404, and a fifth sensor parameter 405 are plotted. For each sensor parameter 401, 402, 403, 404, 405, an accuracy 410 is indicated in the form of a bar, wherein a shaded area of the respective bar indicates what accuracy would be lost if the respective sensor parameter 401, 402, 403, 404, 405 were set to a predetermined value. Thus, the smaller the shaded area, the less influence that this sensor parameter 401, 402, 403, 404, 405 would have on the accuracy 410.

FIG. 6 shows a computing time diagram 420 in which a computing time 430 of the first sensor parameter 401, the second sensor parameter 402, the third sensor parameter 403, the fourth sensor parameter 404 and the fifth sensor parameter 405 is plotted. For each sensor parameter 401, 402, 403, 404, 405, the computing time 430 is indicated in the form of a bar, wherein a shaded area of the respective bar indicates which computing time could be gained if the respective sensor parameter 401, 402, 403, 404, 405 were set to a predetermined value. Thus, the larger the shaded area, the more computing time could be gained by defining this sensor parameter 401, 402, 403, 404, 405.

For both FIG. 5 and FIG. 6, a different number of sensor parameters 401, 402, 403, 404, 405 may also be provided. In particular, the illustrations of FIGS. 5 and 6 clearly show that individual ones of the sensor parameters 401, 402, 403, 404, 405, for example, the second sensor parameter 402 only contribute a small amount to the accuracy 410, but result in a large amount of computing time 430. This may be used to set the second sensor parameter 402 to a predetermined value within the range of values of the second sensor parameter 402, as this reduces the computing time 430 very significantly and the accuracy 410 suffers only marginally. This may be expressed, for example, by the quotient of accuracy 410 and computing time 430.

In particular, if the sensor 110 is a radar sensor, or if the sensor system 100 is a radar sensor system, the sensor parameters 401, 402, 403, 404, 405 may comprise a standard deviation of an average noise of the sensor data, a shift in a detection probability, a maximum antenna gain, a measure of noise, a comprehensive system loss, and/or an average radar cross-section. The standard deviation of the average noise of the sensor data may be between zero and eight dB. The displacement of the detection probability may be between minus five and five. The maximum antenna gain may be between ten and twenty-five dBs. The level of noise may be between ten and twenty. The overall system loss may be between zero and twenty dB. The average radar cross-section may be between minus ten and ten dBsm. In particular, if the sensor system 100 is a lidar sensor system and the sensor 110 is a lidar sensor, the sensor parameters may comprise a number of scan layers, an array of scan layers, an intensity, a motion blur, a rolling shutter, and/or an atmospheric dampening. In particular, if the sensor system 100 is a camera sensor system and the sensor 110 is a camera, the sensor parameters may comprise a vignetting, a lens distortion, an influence of a color filter, a windshield model, and/or weather influences.

The invention further comprises a method for training a detection algorithm, wherein the detection algorithm is trained with simulated sensor data, wherein the simulated sensor data is evaluated with the method for evaluating a sensor model discussed in connection with FIGS. 1-6.

The invention also comprises a sensor system 100 having a sensor 110 and an evaluation unit 120, wherein the evaluation unit 120 is configured to perform a detection algorithm, wherein the detection algorithm is trained with the method according to the invention for training the detection algorithm.

Although the invention has been described in detail by means of the preferred exemplary embodiments, the invention is not limited to the disclosed examples and other variations may be derived therefrom by a person skilled in the art without departing from the scope of protection of the invention.

1. A method for evaluating a sensor model, wherein real-world sensor data is compared to simulated sensor data, the method comprising:
defining sensor parameters to be analyzed and a range of values for each of the sensor parameters to be analyzed;
generating input values for the sensor model, wherein first input values are generated by a simulation of a behavior of a sensor and second input values comprise real-world sensor values;
assessing the simulation of the behavior of the sensor with respect to an accuracy;
assessing the simulation of the behavior of the sensor with respect to a computing time; and
performing a sensitivity analysis using the accuracy and the computing time.

2. The method according to claim 1, further comprising:
determining a quotient of accuracy and the computing time in the sensitivity analysis; and
setting a sensor parameter of the sensor parameters to be analyzed to a defined value for which the quotient of accuracy and the computing time is as small as possible.

3. The method according to claim 2, further comprising:
repeating the method; and
setting a further sensor parameter of the sensor parameters to be analyzed for which the quotient of accuracy and the computing time is as small as possible to another defined value.

4. The method according to claim 2, further comprising:
repeating the method until all of the sensor parameters to be analyzed are set to a corresponding defined value,
wherein the quotient of accuracy and the computing time are below a predetermined value.

5. The method according to claim 1, further comprising:
comparing the first input values and the second input values to assess the simulation of the behavior of the sensor with respect to the accuracy.

6. The method according to claim 1, further comprising:
measuring the computing time when assessing the simulation of the behavior of the sensor with respect to the computing time.

7. The method according to claim 1, further comprising:
generating the second input values by the sensor.

8. The method according to claim 1, further comprising:
determining a scenario for the first input values based on the second input values.

9. A method for training a detection algorithm, comprising:
training the detection algorithm with simulated sensor data; and
evaluating the simulated sensor data with the method according to claim 1.

10. A sensor system comprising:
the sensor; and
an evaluation unit configured to perform the detection algorithm,
wherein the detection algorithm is trained on the method for training the detection algorithm according to claim 9.
